(19) United States
(12) Patent Application Publication
(10) Pub. No.: US 2025/0199698 A1
(43) Pub. Date: Jun. 19, 2025

(54) Computing-In-Memory Chip Architecture, Packaging Method, and Apparatus

(71) Applicant: Hangzhou Zhicun (Witmem) Technology Co., Ltd., Hangzhou (CN)

(72) Inventors: Yu TIAN, Hangzhou (CN); Xinjie GUO, Hangzhou (CN); Xuguang SUN, Hangzhou (CN)

(21) Appl. No.: 18/766,475

(22) Filed: Jul. 8, 2024

(30) Foreign Application Priority Data
Dec. 13, 2023 (CN) 202311717830.1

(51) Int. Cl. G06F 3/06

(52) U.S. Cl. CPC G06F 3/0625; G06F 3/0659; G06F 3/0673

(57) ABSTRACT

A computing-in-memory system, a packaging method for a computing-in-memory system, and an apparatus are provided. The computing-in-memory system includes: a plurality of first chips each integrated with one or more arrays of computing-in-memory cells of a computing-in-memory system, and arranged to overlap each other, where the one or more arrays of computing-in-memory cells are configured to perform computations on received data; a second chip integrated with a peripheral analog circuit IP core and a digital circuit IP core of the computing-in-memory system; and an interface module configured to communicatively couple the second chip to each first chip.

### CROSS REFERENCE TO RELATED APPLICATION

This application claims priority to Chinese Patent Application No. 202311717830.1, filed on Dec. 13, 2023, the contents of which are hereby incorporated by reference in their entirety for all purposes.

### TECHNICAL FIELD

The present disclosure relates to the technical field of computer-in-memory systems, sometimes called computing-in-memory chips, and in particular, to a computing-in-memory chip architecture, a packaging method for a computing-in-memory chip, and an apparatus-a computing-in-memory system or subsystem.

### BACKGROUND

The von Neumann architecture on which computers typically operate includes two separate parts, namely, a memory and a processor. When instructions are executed, data needs to be written to the memory, instructions and data are read from the memory in sequence via the processor, and finally execution results are written back to the memory. Accordingly, data is frequently transferred between the processor and the memory. If a transfer speed of the memory cannot match an operating speed of the processor, the computing power of the processor may be limited. For example, in a hypothetical system, it takes 1 ns for the processor to execute an instruction, while it takes 10 ns for the instruction to be read and transferred from the memory. This significantly reduces the operating speed of the processor, and thus reduces the performance of the entire computing system.

Methods described in this section are not necessarily methods that have been previously conceived or employed. It should not be assumed that any of the methods described in this section is considered to be the prior art because it is included in this section, unless otherwise indicated expressly. Similarly, the problem mentioned in this section should not be considered to be recognized in any prior art, unless otherwise indicated expressly.

### SUMMARY

According to a first aspect of the present disclosure, a computing-in-memory system is provided. The computing-in-memory system includes: a plurality of first chips (e.g., integrated circuits) each including one or more arrays of computing-in-memory cells, and arranged to overlap each other, where the one or more arrays of computing-in-memory cells are configured to perform computations on received data; a second chip (e.g., integrated circuits) that includes a peripheral analog circuit IP core and a digital circuit IP core; and an interface module configured to communicatively couple the second chip to each first chip.

According to a second aspect of the present disclosure, a packaging method for a computing-in-memory system is provided. The packaging method includes: integrating one or more arrays of computing-in-memory cells of the computing-in-memory system on a plurality of first chips arranged to overlap each other, where the one or more arrays of computing-in-memory cells are configured to perform computations on received data; integrating a peripheral analog circuit IP core and a digital circuit IP core of the computing-in-memory chip on a second chip; and packaging the plurality of first chips and the second chip, where the second chip is communicatively coupled to each first chip.

According to a third aspect of the present disclosure, an apparatus is provided which includes the computing-in-memory system described above.

These and other aspects of the present disclosure will be apparent from the embodiments described below, and will be clarified with reference to the embodiments described below.

### BRIEF DESCRIPTION OF THE DRAWINGS

More details, features, and advantages of the present disclosure are disclosed in the following description of example embodiments with reference to the accompanying drawings, in which:

FIG. 1 is a schematic diagram of a computing-in-memory chip architecture according to some embodiments of the present disclosure;

FIG. 2 is a schematic diagram of a second chip in a computing-in-memory chip architecture according to some embodiments of the present disclosure;

FIG. 3 is a flow chart of a packaging method for a computing-in-memory system according to some embodiments of the present disclosure;

FIG. 4 is a flow chart of a packaging method for a computing-in-memory system according to some other embodiments of the present disclosure; and

FIG. 5 is a flow chart of a packaging method for a computing-in-memory system according to yet other embodiments of the present disclosure.

### DETAILED DESCRIPTION OF EMBODIMENTS

It is noted that although terms such as first, second and third may be used herein to describe various elements, components, areas, layers and/or parts, these elements, components, areas, layers and/or parts should not be limited by these terms. These terms are merely used to distinguish one element, component, area, layer or part from another. Therefore, a first element, component, area, layer or part discussed below may be referred to as a second element, component, area, layer or part without departing from the teaching of the present disclosure.

Terms regarding spatial relativity such as “under”, “below”, “lower”, “beneath”, “above” and “upper” may be used herein to describe the relationship between one element or feature and another element(s) or feature(s) as illustrated in the figures. It is noted that these terms are intended to cover different orientations of a device in use or operation in addition to the orientations depicted in the figures. For example, if the device in the figures is turned over, an element described as being “below other elements or features” or “under other elements or features” or “beneath other elements or features” will be oriented to be “above other elements or features”. Thus, the example terms “below” and “beneath” may cover both orientations “above” and “below”. Terms such as “before” or “ahead” and “after” or “then” may similarly be used, for example, to indicate the order in which light passes through elements. The device may be oriented in other ways (rotated by 90° or in other orientations), and the spatially relative descriptors used herein are interpreted correspondingly. In addition, it will also be understood that when a layer is referred to as being “between two layers”, it may be the only layer between the two layers, or there may also be one or more intermediate layers.

The terms used herein are merely for the purpose of describing specific embodiments and are not intended to limit the present disclosure. As used herein, the singular forms “a”, “an”, and “the” are intended to include plural forms as well, unless otherwise explicitly indicated in the context. Further, it is noted that the terms “comprise” and/or “include”, when used in the description, specify the presence of described features, entireties, steps, operations, elements and/or components, but do not exclude the presence or addition of one or more other features, entireties, steps, operations, elements, components and/or groups thereof. As used herein, the term “and/or” includes any and all combinations of one or more of the associated listed items, and the phrase “at least one of A and B” refers to only A, only B, or both A and B.

It is noted that when an element or a layer is referred to as being “on another element or layer”, “connected to another element or layer”, “coupled to another element or layer”, or “adjacent to another element or layer”, the element or layer may be directly on another element or layer, directly connected to another element or layer, directly coupled to another element or layer, or directly adjacent to another element or layer, or there may be an intermediate element or layer. On the contrary, when an element is referred to as being “directly on another element or layer”, “directly connected to another element or layer”, “directly coupled to another element or layer”, or “directly adjacent to another element or layer”, there is no intermediate element or layer. However, under no circumstances should “on” or “directly on” be interpreted as requiring one layer to completely cover the underlying layer.

Embodiments of the present disclosure are described herein with reference to schematic illustrations (and intermediate structures) of idealized embodiments of the present disclosure. On this basis, variations in an illustrated shape, for example as a result of manufacturing techniques and/or tolerances, should be expected. Therefore, the embodiments of the present disclosure should not be interpreted as being limited to a specific shape of an area illustrated herein, but should comprise shape deviations caused due to manufacturing, for example. Therefore, the area illustrated in a figure is schematic, and the shape thereof is neither intended to illustrate the actual shape of the area of a device, nor to limit the scope of the present disclosure.

Unless otherwise defined, all terms (including technical and scientific terms) used herein have the same meanings as commonly understood by those of ordinary skill in the art to which the present disclosure belongs. It is further noted that the terms such as those defined in dictionaries should be interpreted as having meanings consistent with the meanings thereof in relevant fields and/or in the context of the description, and will not be interpreted in an ideal or too formal sense, unless defined explicitly herein.

The von Neumann architecture on which computers typically operate includes two separate parts, namely, a memory and a processor. When instructions are executed, data needs to be written to the memory, instructions and data are read from the memory in sequence via the processor, and finally execution results are written back to the memory. Accordingly, data is frequently transferred between the processor and the memory. If a transfer speed of the memory cannot match an operating speed of the processor, the computing power of the processor may be limited, and thus the performance of the entire computing system is reduced.

To improve the computing power of the processor and alleviate the above problem, computing-in-memory chips (sometimes called computing-in-memory systems or subsystems) have been rapidly developed. Such chips have a computing unit with computing power embedded into a memory. Control of an operating mode of the computing-in-memory chip may allow both data computation and data storage in the chip. Since there is no need to frequently transfer data between the processor and the memory, data transfer latency and power consumption can be reduced, and the performance of an entire computing system that includes such chips can be improved.

The inventors notice that such computing-in-memory chips usually include a computing unit with a computing function, a unit for processing and storing computed data, etc. The computing unit is usually implemented based on analog circuits and has low requirements for a process node, while other units are mainly implemented based on digital circuits and have high requirements for a process node. A process node is sometimes defined as the measure of the size of a chip's transistors and other components, and is often specified in terms of a minimum metal or conductor line width or feature pitch. Low requirements for a process node correspond to relatively large minimum metal or conductor line width or feature pitch, while high requirements for a process node correspond to relatively small minimum metal or conductor line width or feature pitch. Currently, such computing-in-memory chips can be integrated by integrating the computing unit and other units on different chips. In this context, if the rate of data computations (e.g., number of data computations per second) by the computing unit is large, the communication rate and transfer efficiency between chips may be low, resulting in a large data transfer latency. This problem is more significant when there is a large number of chips (e.g., computing-in-memory chips) on which the computing unit is located.

In view of the above technical problems, one or more embodiments of the present disclosure provide a computing-in-memory chip architecture (sometimes called a system architecture or an architecture for a computing-in-memory system), a packaging method for a computing-in-memory system, and an apparatus. Various embodiments of the present disclosure are described in detail below in conjunction with the drawings.

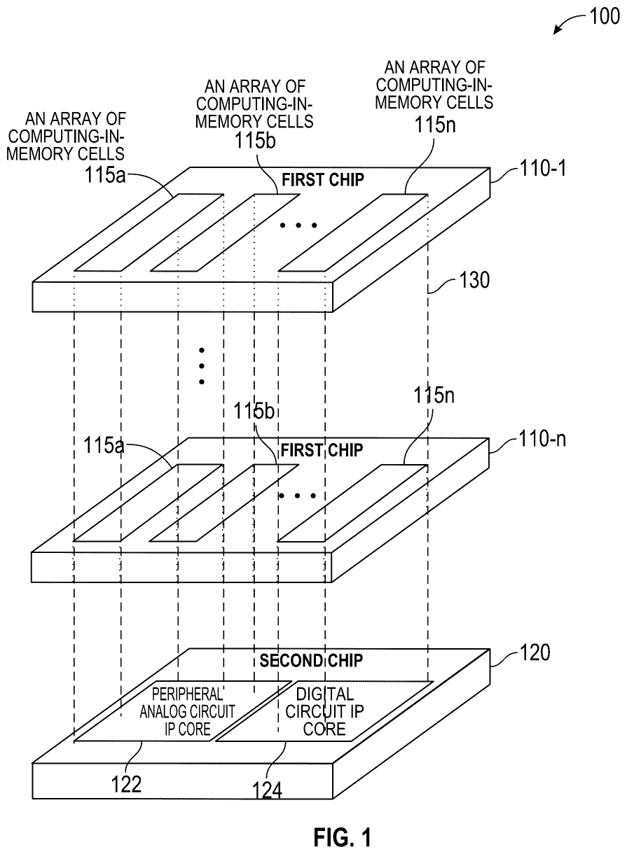

FIG. 1 illustrates a schematic diagram of a computing-in-memory chip architecture 100 (e.g., a computing-in-memory system or subsystem) according to some embodiments of the present disclosure. As shown in FIG. 1, the computing-in-memory chip architecture 100 may include: a plurality of first chips 110-1 to 110-n that each include one or more arrays of computing-in-memory cells 115a to 115n of a computing-in-memory chip, and arranged to overlap each other, where the one or more arrays of computing-in-memory cells are configured to perform computations on received data; a second chip 120 that includes a peripheral analog circuit IP core 122 and a digital circuit IP core 124 of the computing-in-memory chip; and an interface module 130 configured to communicatively couple the second chip 120 to each of the first chips 110-1 to 110-n.

It is noted that the computing-in-memory chip architecture may refer to a computing-in-memory system, a computing-in-memory chip interconnection integrated structure, a computing-in-memory chip product, etc.

In addition, in a production process of chips (e.g. integrated circuits), the more modules or units that are integrated on a chip, the more errors can occur (e.g., during production), resulting in an increased defect rate of the chips. By respectively integrating the arrays of computing-in-memory cells of the computing-in-memory system, and the peripheral analog circuit IP core and the digital circuit IP core on different chips, and packaging these chips together to form a computing-in-memory system, the yield (e.g., manufacturing or production yield of the chips) of the computing-in-memory system may be improved, and the aforementioned problems with data transfers between the arrays of computing-in-memory cells, and the peripheral analog circuit IP core and the digital circuit IP core may be effectively avoided.

In addition, by stacking the plurality of first chips on one another, an arrangement of arrays of a larger number of computing-in-memory cells is allowed without an increase in the area of a chip package, thereby significantly improving the computing power of the entire computing-in-memory system, reducing production costs, and further expanding usage scenarios of the computing-in-memory system.

According to some embodiments of the present disclosure, the arrays of computing-in-memory cells on the first chips 110-1 to 110-n may be implemented based on an analog circuit (e.g., multiple instances of one or more analog circuits), configured to (e.g., used to) perform computations on received analog data, e.g., for computing a voltage and a current according to Kirchhoff's law or Ohm's law, various addition operations, multiplication operations, matrix multiplication operations, etc. It is noted that the arrays of computing-in-memory cells on the first chips 110-1 to 110-n may also be implemented based on a digital circuit (e.g., multiple instances of one or more digital circuits). It is also noted that, although n arrays of computing-in-memory cells are shown on each of the first chips 110-1 to 110-n in FIG. 1, the first chip may include only one array of computing-in-memory cells. Furthermore, the one or more first chips may include one or more computing-in-memory cells (or arrays of such cells) based on (e.g., that are or comprise) digital circuits and one or more computing-in-memory cells (or arrays of such cells) based on (e.g., that are or comprise) analog circuits.

According to some embodiments of the present disclosure, the peripheral analog circuit IP core 122 on the second chip 120 is a functional module based on an analog signal (e.g., based on circuits (e.g., analog circuits) that perform computations on analog data). In some examples, the peripheral analog circuit IP core 122 may include one or more of: a programming circuit module coupled to the one or more arrays of computing-in-memory cells and configured to perform data programming on (e.g., storing data in) the one or more arrays of computing-in-memory cells; a digital-to-analog conversion module coupled to the one or more arrays of computing-in-memory cells and configured to convert digital data to be input to the one or more arrays of computing-in-memory cells into analog data; an analog-to-digital conversion module coupled to the one or more arrays of computing-in-memory cells and configured to convert analog data computed by the one or more arrays of computing-in-memory cells into digital data; a phase-locked loop; and an oscillator.

In some other examples, the peripheral analog circuit IP core 122 may further include, for example, an input interface module, an input register file, an output register file, and an output interface module.

In still other examples, the peripheral analog circuit IP core may further include a calibration module for calibrating data obtained by the one or more arrays of computing-in-memory cells; and a compensation module for performing signal compensation on the data obtained by the one or more arrays of computing-in-memory cells. The use of the calibration module and the compensation module may further increase the accuracy of the chips, thereby effectively mitigating the interference of data transfer between different chips.

According to some embodiments of the present disclosure, the digital circuit IP core 124 on the second chip 120 is a functional module based on a digital signal (e.g., based on circuits (e.g., digital circuits) that perform computations on digital data). In some examples, the digital circuit IP core 124 may include one or more of: a post-processing operation circuit configured to perform a post-processing operation on digital data produced by the analog-to-digital conversion module; a random-access memory (RAM); a central processing unit (CPU); a graphics processing unit (GPU); and a peripheral interface module.

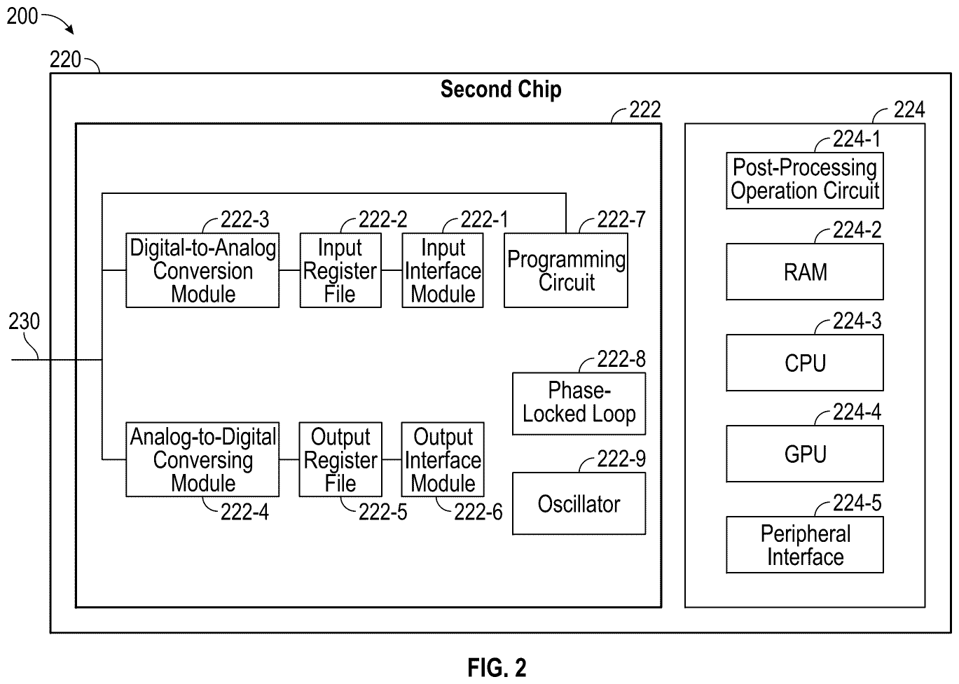

The modules of the peripheral analog circuit IP core and the digital circuit IP core will be described in detail below with reference to FIG. 2.

According to some embodiments of the present disclosure, the interface module 130 may be configured to transfer data between each of the first chips 110-1 to 110-n and the second chip 120 through an analog signal, or one or more analog signals, or both analog and digital signals.

When the computing unit and the other units are integrated on different chips, information is usually transferred between the chips through digital signals, resulting in a high transfer power consumption. For example, transfer of data that is 8-bits wide requires eight digital signals, but only one analog signal. Therefore, the use of an analog signal to transfer data between each first chip and the second chip may significantly reduce the number of signals required for data transfer, thereby effectively reducing power consumption.

According to some embodiments of the present disclosure, the interface module 130 may be an electrical interconnect between the first chip and the second chip. For example, the electrical interconnect may be a metal pin on the first chip and the second chip. According to some other embodiments of the present disclosure, the interface module 130 may also be a bus (e.g., a communications bus) through which signals are transferred between the first chip and the second chip. According to still other embodiments of the present disclosure, the interface module 130 may include a through-silicon via (TSV) structure that connects nodes (e.g., in circuits) in the first chip with nodes in the second chip.

FIG. 2 illustrates a schematic diagram of a second chip 220 of a computing-in-memory chip architecture 200 according to some embodiments of the present disclosure. For the purpose of simplicity, FIG. 2 illustrates only the second chip 220 and an interface module 230 (e.g., a communication bus). It is noted that the computing-in-memory chip architecture 200 may further include a plurality of first chips (including arrays of computing-in-memory cells) similar to those in the computing-in-memory chip architecture 100 described with reference to FIG. 1. For the purpose of simplicity, features, operations, and functions of the similar components are omitted from the discussion of FIG. 2.

As shown in FIG. 2, a peripheral analog circuit IP core 222 in the computing-in-memory chip architecture 200 (e.g., a computing-in-memory system or subsystem) may include: an input interface module 222-1 for receiving data to be processed (e.g., via one or more communication busses, such as interface module 130 or 230; an input register file 222-2 coupled to the input interface module 222-1 and configured to temporarily store data to be processed from the input interface module 222-1; a digital-to-analog conversion module 222-3 coupled (e.g., by one or more communication busses, such as interface module 130 or 230) to one or more arrays of computing-in-memory cells 215a to 215n of the first chip and the input register file 222-2, and configured to convert digital data from the input interface module 222-1 into analog data; an analog-to-digital conversion module 222-4 also coupled (e.g., by one or more communication busses, such as interface module 130 or 230) to the one or more arrays of computing-in-memory cells 215a to 215n of the first chip, and configured to convert analog data obtained by processing via (e.g., performed by) the arrays of computing-in-memory cells into digital data; an output register file 222-5 coupled to the analog-to-digital conversion module 222-4 and configured to temporarily store digital data produced by converting the analog data obtained by processing via the one or more arrays of computing-in-memory cells 215a to 215n; an output interface module 222-6 coupled to the output register file 222-5 and configured to output the registered digital data; a programming circuit 222-7 coupled (e.g., by one or more communication busses, such as interface module 130 or 230) to the one or more arrays of computing-in-memory cells 215a to 215n of the first chip, which, in some examples, may include a voltage generation circuit and a voltage control circuit, so as to perform data programming on the one or more arrays of computing-in-memory cells of the first chip by controlling a voltage so as to store data in the one or more arrays of computing-in-memory cells of the first chip; a phase-locked loop 222-8 for providing a synchronized clock signal; and an oscillator 222-9 for generating a stable signal with a specific frequency.

Still referring to FIG. 2, in some embodiments, a digital circuit IP core 224 in the computing-in-memory chip architecture 200 includes one or more of: a post-processing operation circuit 224-1 configured to, for example, perform post-processing operations such as shifting or activation on digital data produced by the analog-to-digital conversion module 222-4; a random-access memory (RAM) 224-2; a central processing unit (CPU) 224-3; a graphics processing unit (GPU) 224-4; and a peripheral interface 224-5.

It is noted that FIG. 2 illustrates one implementation of the peripheral analog circuit IP core and the digital circuit IP core in the computing-in-memory chip architecture for illustrative purposes only. The peripheral analog circuit IP core may further include one or more other modules, such as an analog data preprocessing module, and the digital circuit IP core may also include one or more other modules, such as a codec module. In addition, although FIG. 2 illustrates particular ways of computing between modules included in the peripheral analog circuit IP core and the digital circuit IP core, it is understood that, these modules may also be coupled in any other manner. The scope of protection of the present disclosure is not limited in this respect.

According to some embodiments of the present disclosure, the peripheral analog circuit IP core may include one or more modules, and the second chip may include one or more sub-chips, each of which includes one or more modules of the peripheral analog circuit IP core or a combination thereof.

In some examples, different modules in each peripheral analog circuit IP core may have different requirements for a chip process node (corresponding to a minimum metal or conductor line width or feature pitch). In this case, integration of different modules or a combination thereof in the peripheral analog circuit IP core on different chips (e.g., integrated circuits) makes it possible to select an appropriate process node for different modules in the peripheral analog circuit IP core. For example, the analog-to-digital conversion module 222-4 and the digital-to-analog conversion module 222-3 can be integrated on one chip (e.g., a sub-chip of the second chip) through a process node with a relatively large line width (e.g., minimum metal line width), while the programming circuit 222-7 can be integrated on another chip (e.g., another sub-chip of the second chip) through a process node with a relatively small line width (e.g., minimum metal line width). In this way, the performance of the chips can be ensured, and the cost can be reduced. In addition, as described above, this also facilitates yield improvement and fault detection of the chips.

Although the above embodiments only describe integration of any one or a combination of the digital-to-analog conversion module, the analog-to-digital conversion module, and the programming circuit module on different sub-chips of the second chip, it is understood that, in a case that the peripheral analog circuit IP core of the computing-in-memory system includes the input interface module, the input register file, the output register file, and/or the output interface module, as described above, and any other optional modules, any one or a combination of these modules may also be integrated on (e.g., positioned, or fabricated on) different sub-chips of the second chip.

According to some other embodiments of the present disclosure, the digital circuit IP core 124/224 may also include one or more modules, and the second chip 120/220 may include one or more sub-chips that each include any one of the one or more modules of the digital circuit IP core or a combination thereof.

Similarly, in some examples, different modules in each digital circuit IP core 124/224 may have different requirements for a chip process node. In this case, integration of different modules or a combination thereof in the digital circuit IP core on different chips (e.g., different sub-chips of the second chip 120/220) makes it possible to select an appropriate process node for each of the different modules in the digital circuit IP core 124/224. For example, the post-processing operation circuit 224-1 can be integrated on one chip through a process node with a relatively large line width (e.g., relatively large minimum line width), while the CPU 224-3, the GPU 224-4, etc. can be integrated on another chip through a process node with a relatively small line width (e.g., relatively small minimum line width). It is noted that, typically, chips made using a process node with a relatively small line width are more expensive to manufacture than chips made using a process with a relatively large line width. By manufacturing different chips and/or sub-chips of the computing-in-memory system using different process nodes, the performance of the chips and computing-in-memory system can be ensured, and the cost of the computing-in-memory system can be reduced. In addition, as described above, this also facilitates yield improvement and fault detection of the chips.

Although the above embodiments only describe integration of any one or a combination of the post-processing operation circuit, the CPU, and the GPU on different sub-chips of the second chip, it is understood that, in a case in which the digital circuit IP core of the computing-in-memory system includes DRAM, the peripheral interface module, as described above, and any other modules, any one or a combination of these modules may also be integrated on different sub-chips.

According to some embodiments of the present disclosure, the one or more arrays of computing-in-memory cells may be integrated (e.g., included or manufactured) on the plurality of first chips through (e.g., using) a first process node, and the peripheral analog circuit IP core and the digital circuit IP core may be integrated (e.g., included or manufactured) on the second chip through (e.g., using) a second process node different from the first process node.

In some examples, the arrays of computing-in-memory cells may be implemented using analog circuits. Since analog signals in analog circuits are susceptible to noise interference, integration of the arrays of computing-in-memory cells, and the peripheral analog circuit IP core and the digital circuit IP core on different chips through different process nodes may effectively mitigate the interference between these modules, and ensure the accuracy and credibility of data. In addition, based on different implementations of the two types of circuits, more appropriate process nodes may be selected, thereby reducing process costs.

According to some embodiments of the present disclosure, the line width (e.g., minimum line width) of the second process node for integrating the peripheral analog circuit IP core and the digital circuit IP core may be less than a line width (e.g., minimum line width) of the first process node for integrating the arrays of one or more computing-in-memory cells.

In some examples, the peripheral analog circuit IP core and the digital circuit IP core may be integrated on the second chip through a process node with a line width (e.g., minimum line width) of 14 nanometers (nm) or 7 nm.

In other examples, the arrays of one or more computing-in-memory cells may be integrated on the first chip through a process node with a line width (e.g., minimum line width) of 55 nm, 40 nm, or 28 nm.

In general, an implementation of a respective chip based on analog circuitry (e.g., an integrated circuit that comprises analog circuitry) has low requirements for a process node, because the use of an advanced process node with a smaller line width (e.g., minimum line width) may cause distortion of analog signals being processed or conveyed by the respective chip, due to noise and reduce the accuracy of those signals. By contrast, an implementation of a respective chip based on a digital circuit (e.g., a chip that comprises digital circuitry) usually has high requirements for a process node, so as to improve the operating performance and accuracy of a chip. Therefore, the use of the process node with a smaller line width (e.g., minimum line width) to integrate the peripheral analog circuit IP core and the digital circuit IP core, and the use of the process node with a larger line width (e.g., minimum line width) to integrate the arrays of one or more computing-in-memory cells based on an analog circuit makes it possible to avoid high cost, excessive power consumption, and possible data distortion resulting from the chips of the entire system using the advanced process nodes with a smaller line width (e.g., minimum line width) to integrate different chips, and to avoid low operating performance of chips resulting from all of the chips using the process nodes with a larger line width (e.g., minimum line width) to integrate different chips. The use of different process nodes for different chips of the computing-in-memory system allows for improved performance, power consumption, and cost, and for beneficial trade-offs between performance, power consumption, and cost.

According to some embodiments of the present disclosure, the one or more arrays of computing-in-memory cells, and the peripheral analog circuit IP core and the digital circuit IP core may also be integrated, through a same process node, on each first chip and the second chip, respectively.

In this case, a more appropriate process node can be selected as needed. For example, when requirements for chip performance are not high and reduction of the power consumption and cost is desired, a process node with a line width of 28 nm can be selected to integrate the one or more arrays of computing-in-memory cells, and the peripheral analog circuit IP core and the digital circuit IP core on the first chip and the second chip, respectively. For another example, if high chip performance is desired, a process node with a line width (e.g., minimum line width) smaller than 28 nm can be selected to integrate the one or more arrays of computing-in-memory cells, and the peripheral analog circuit IP core and the digital circuit IP core on the first chip and the second chip, respectively.

The use of the same process node (that is, the same line width) to integrate different chips may simplify operations required to integrate the chips and their complexity.

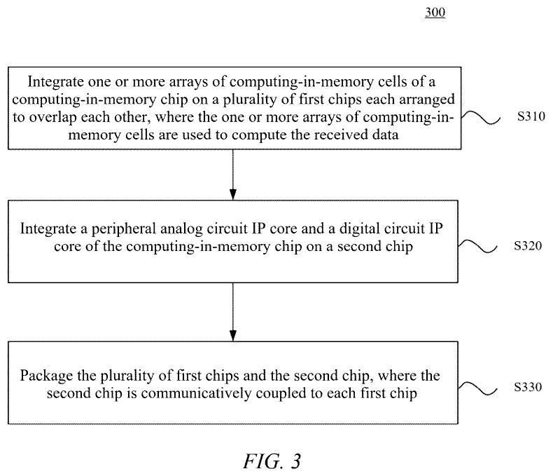

FIG. 3 illustrates a flow chart of a packaging method 300 for a computing-in-memory system according to some embodiments of the present disclosure. As shown in FIG. 3, the packaging method 300 may include: step S310: integrating one or more arrays of computing-in-memory cells of the computing-in-memory system on a plurality of first chips that are arranged to overlap each other, where the one or more arrays of computing-in-memory cells are configured to perform computations on received data; step S320: integrating a peripheral analog circuit IP core and a digital circuit IP core of the computing-in-memory chip on a second chip; and step S330: packaging the plurality of first chips and the second chip, where the second chip is communicatively coupled to each first chip.

By integrating the arrays of computing-in-memory cells, and the peripheral analog circuit IP core and the digital circuit IP core of the computing-in-memory system on different chips, and packaging these chips together, the yield of the computing-in-memory system may be improved, and the interference between the arrays of computing-in-memory cells, and the peripheral analog circuit IP core and the digital circuit IP core may be effectively avoided.

In addition, by stacking the plurality of first chips on one another, an arrangement of arrays of a larger number of computing-in-memory cells is allowed without an increase in the area of a chip package, thereby significantly improving (e.g., increasing) the computing power of the entire computing-in-memory chip, reducing production costs, and further expanding usage scenarios of the computing-in-memory system.

According to some embodiments of the present disclosure, step S310 of integrating the one or more arrays of computing-in-memory cells of the computing-in-memory chip on the plurality of first chips may include: integrating, through a first process node, the one or more arrays of computing-in-memory cells on each of the plurality of first chips; and step S320 of integrating the peripheral analog circuit IP core and the digital circuit IP core of the computing-in-memory system on the second chip may include: integrating, through a second process node different from the first process node, the peripheral analog circuit IP core and the digital circuit IP core on the second chip.

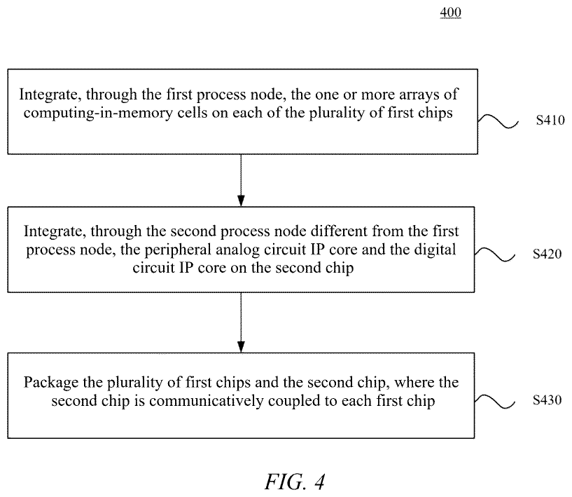

FIG. 4 illustrates a flow chart of a packaging method 400 for a computing-in-memory system according to such embodiments of the present disclosure. As shown in FIG. 4, the packaging method 400 may include: step S410: integrating, through the first process node, the one or more arrays of computing-in-memory cells on each of the plurality of first chips; step S420: integrating, through the second process node different from the first process node, the peripheral analog circuit IP core and the digital circuit IP core on the second chip; and step S430, which is similar to step S330 in FIG. 3: packaging the plurality of first chips and the second chip, where the second chip is communicatively coupled to each first chip.

By integrating, through different process nodes, the arrays of computing-in-memory cells and the peripheral analog circuit IP core and the digital circuit IP core on different chips, interference between the arrays of computing-in-memory cells, and the peripheral analog circuit IP core and the digital circuit IP core may be effectively mitigated, and the accuracy and credibility of data may be ensured. In addition, based on different implementations of the two types of circuits, more appropriate process nodes may be selected doe producing the respective chips, thereby reducing process (e.g., production) costs.

According to some embodiments of the present disclosure, the line width (e.g., minimum line width) of the second process node may be less than the line width (e.g., minimum line width) of the first process node.

According to some embodiments of the present disclosure, the one or more arrays of computing-in-memory cells, and the peripheral analog circuit IP core and the digital circuit IP core may be integrated, through a same process node, on each of the plurality of first chips and the second chip, respectively.

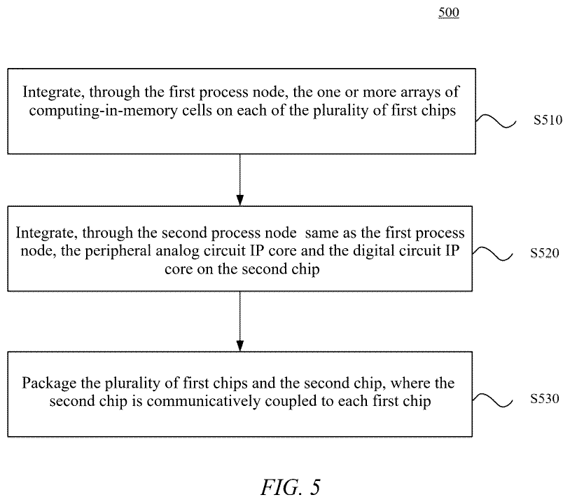

FIG. 5 illustrates a flow chart of a packaging method 500 for a computing-in-memory system according to such embodiments of the present disclosure. As shown in FIG. 5, the packaging method 500 may include: step S510: integrating, through the first process node, the one or more arrays of computing-in-memory cells on each of the plurality of first chips; step S520: integrating, through the second process node same as the first process node, the peripheral analog circuit IP core and the digital circuit IP core on the second chip; and step S530, which is similar to step S330 in FIG. 3 and step S430 in FIG. 4: packaging the plurality of first chips and the second chip, where the second chip is communicatively coupled to each first chip.

As described above, in this case, a more appropriate process node can be selected as needed, and operations required to integrate (e.g., produce) the chips and their complexity can be simplified.

According to some embodiments of the present disclosure, in step S330, the second chip may be communicatively coupled to each of the plurality of first chips via one or more through-silicon vias (TSVs).

According to some embodiments of the present disclosure, in step S330, each first chip is communicatively coupled to the second chip, such that data may be transferred through one more analog signals.

When the computing unit and other units are integrated on different chips, information is usually transferred between the chips through a digital signal, resulting in a high transfer power consumption. For example, transfer of data that is 8-bit wide requires eight digital signals, but only one analog signal. Therefore, the use of the analog signal to transfer data between each first chip and the second chip may significantly reduce the number of signals required for data transfer, thereby effectively reducing the power consumption.

According to some embodiments of the present disclosure, the peripheral analog circuit IP core may include one or more of: a programming circuit module coupled to the one or more arrays of computing-in-memory cells and configured to perform data programming on the one or more arrays of computing-in-memory cells; a digital-to-analog conversion module coupled to the one or more arrays of computing-in-memory cells and configured to convert digital data to be input to the one or more arrays of computing-in-memory cells into analog data; an analog-to-digital conversion module coupled to the one or more arrays of computing-in-memory cells and configured to convert analog data computed by the one or more arrays of computing-in-memory cells into digital data; a phase-locked loop; and an oscillator.

According to some embodiments of the present disclosure, the peripheral analog circuit IP core may include one or more modules, and the second chip may include one or more sub-chips that each include any of the one or more modules of the peripheral analog circuit IP core or a combination thereof.

According to some embodiments of the present disclosure, the digital circuit IP core may include one or more of: a post-processing operation circuit configured to perform a post-processing operation on the digital data converted by the analog-to-digital conversion module; a random-access memory (RAM); a central processing unit (CPU); a graphics processing unit (GPU); and a peripheral interface module.

According to some embodiments of the present disclosure, the digital circuit IP core may include one or more modules, and the second chip may include one or more sub-chips that each include any of the one or more modules of the digital circuit IP core or a combination thereof.

It is noted that the steps of the packaging methods 300-500 shown in FIGS. 3-5 may correspond to the modules in the computing-in-memory chip architectures 100-200 described with reference to FIGS. 1-2. Therefore, the components, functions, features, and advantages described above for the computing-in-memory chip architectures 100-200 are applicable to the packaging methods 300-500 and the steps included therein. For the purpose of brevity, some operations, features, and advantages are not described herein.

According to another aspect of the present disclosure, an apparatus is provided, which includes the computing-in-memory chip architecture described above.

Some example aspects of the present disclosure are described below.

Aspect 1. A computing-in-memory system, including:
a plurality of first chips each including one or more arrays of computing-in-memory cells of a computing-in-memory system, and arranged to overlap each other, where the one or more arrays of computing-in-memory cells are configured to perform computations on received data;
a second chip that includes a peripheral analog circuit IP core and a digital circuit IP core of the computing-in-memory system; and
an interface module configured to communicatively couple the second chip to each first chip.

Aspect 2. The computing-in-memory system according to aspect 1, where the interface module includes a through-silicon via (TSV) structure.

Aspect 3. The computing-in-memory system according to aspect 1 or 2, where the peripheral analog circuit IP core includes one or more of:
a programming circuit module coupled to the one or more arrays of computing-in-memory cells and configured to perform data programming on the one or more arrays of computing-in-memory cells;
a digital-to-analog conversion module coupled to the one or more arrays of computing-in-memory cells and configured to convert digital data to be input to the one or more arrays of computing-in-memory cells into analog data;
an analog-to-digital conversion module coupled to the one or more arrays of computing-in-memory cells and configured to convert analog data computed by the one or more arrays of computing-in-memory cells into digital data;
a phase-locked loop; and
an oscillator.

Aspect 4. The computing-in-memory system according to aspect 1 or 2, where the peripheral analog circuit IP core includes one or more modules, and
where the second chip includes one or more sub-chips that each include any of the one or more modules of the peripheral analog circuit IP core or a combination thereof.

Aspect 5. The computing-in-memory system according to aspect 3, where the digital circuit IP core includes one or more of:
a post-processing operation circuit configured to perform a post-processing operation on the digital data converted by the analog-to-digital conversion module;
a random-access memory (RAM);
a central processing unit (CPU);
a graphics processing unit (GPU); and
a peripheral interface module.

Aspect 6. The computing-in-memory system according to aspect 1 or 5, where the digital circuit IP core includes one or more modules, and
where the second chip includes one or more sub-chips that each include any of the one or more modules of the digital circuit IP core or a combination thereof.

Aspect 7. The computing-in-memory system according to any of aspects 1 to 6, where the one or more arrays of computing-in-memory cells are integrated, through a first process node, on each first chip, and the peripheral analog circuit IP core and the digital circuit IP core are integrated, through a second process node different from the first process node, on the second chip.

Aspect 8. The computing-in-memory system according to aspect 7, where a minimum line width of the second process node is less than a minimum line width of the first process node.

Aspect 9. The computing-in-memory system according to any of aspects 1 to 8, where the one or more arrays of computing-in-memory cells, and the peripheral analog circuit IP core and the digital circuit IP core are respectively integrated, through a same process node, on each first chip and the second chip.

Aspect 10. A packaging method for a computing-in-memory system including:
integrating one or more arrays of computing-in-memory cells of the computing-in-memory system on a plurality of first chips each arranged to overlap each other, where the one or more arrays of computing-in-memory cells are configured to perform computations on received data;
integrating a peripheral analog circuit IP core and a digital circuit IP core of the computing-in-memory system on a second chip; and
packaging the plurality of first chips and the second chip, where the second chip is communicatively coupled to each first chip.

Aspect 11. The packaging method according to aspect 10, where the second chip is communicatively coupled to each of the plurality of first chips via a through-silicon via (TSV).

Aspect 12. The packaging method according to aspect 10, where integrating the one or more arrays of computing-in-memory cells of the computing-in-memory system on the plurality of first chips includes: integrating, through a first process node, the one or more arrays of computing-in-memory cells on each of the plurality of first chips, respectively, and
where integrating the peripheral analog circuit IP core and the digital circuit IP core of the computing-in-memory system on the second chip includes: integrating, through a second process node different from the first process node, the peripheral analog circuit IP core and the digital circuit IP core on the second chip.

Aspect 13. The packaging method according to aspect 12, where a line width (e.g., minimum line width) of the second process node is less than a line width (e.g., minimum line width) of the first process node.

Aspect 14. The packaging method according to aspect 10, where the one or more arrays of computing-in-memory cells, and the peripheral analog circuit IP core and the digital circuit IP core are integrated, through a same process node, on each of the plurality of first chips and on the second chip, respectively.

Aspect 15. The packaging method according to aspect 10, where the peripheral analog circuit IP core includes one or more of:
a programming circuit module coupled to the one or more arrays of computing-in-memory cells and configured to perform data programming on the one or more arrays of computing-in-memory cells;
a digital-to-analog conversion module coupled to the one or more arrays of computing-in-memory cells and configured to convert digital data to be input to the one or more arrays of computing-in-memory cells into analog data;
an analog-to-digital conversion module coupled to the one or more arrays of computing-in-memory cells and configured to convert analog data computed by the one or more arrays of computing-in-memory cells into digital data;
a phase-locked loop; and
an oscillator.

Aspect 16. The packaging method according to aspect 10 or 15, where the peripheral analog circuit IP core includes one or more modules, and
where the second chip includes one or more sub-chips that each include any of the one or more modules of the peripheral analog circuit IP core or a combination thereof.

Aspect 17. The packaging method according to aspect 15, where the digital circuit IP core includes one or more of:
a post-processing operation circuit configured to perform a post-processing operation on the digital data converted by the analog-to-digital conversion module;
a random-access memory (RAM);
a central processing unit (CPU);
a graphics processing unit (GPU); and
a peripheral interface module.

Aspect 18. The packaging method according to aspect 10 or 17, where the digital circuit IP core includes one or more modules, and
where the second chip includes one or more sub-chips that each include any of the one or more modules of the digital circuit IP core or a combination thereof.

Aspect 19. An apparatus, including the computing-in-memory system according to any of aspects 1 to 9.

Although the present disclosure has been illustrated and described in detail with reference to the accompanying drawings and the foregoing description, such illustration and description should be considered illustrative and schematic, rather than limiting; and the present disclosure is not limited to the disclosed embodiments. By studying the accompanying drawings, the disclosure, and the appended claims, those skilled in the art can understand and implement modifications to the disclosed embodiments when practicing the claimed subject matters. In the claims, the word “comprising” does not exclude other elements or steps not listed, the indefinite article “a” or “an” does not exclude plural, and the term “a plurality of” means two or more. The mere fact that certain measures are recited in different dependent claims does not indicate that a combination of these measures cannot be used to get benefit.

1. A computing-in-memory system, comprising:
a plurality of first chips, each including one or more arrays of computing-in-memory cells and arranged to overlap each other, wherein the one or more arrays of computing-in-memory cells are configured to perform computations on received data;
a second chip that includes a peripheral analog circuit IP core and a digital circuit IP core of the computing-in-memory system; and
an interface module configured to communicatively couple the second chip to each first chip.

2. The computing-in-memory system according to claim 1, wherein the interface module comprises a through-silicon via (TSV) structure.

3. The computing-in-memory system according to claim 1, wherein the peripheral analog circuit IP core includes one or more of:
a programming circuit module coupled to the one or more arrays of computing-in-memory cells and configured to perform data programming on the one or more arrays of computing-in-memory cells;
a digital-to-analog conversion module coupled to the one or more arrays of computing-in-memory cells and configured to convert digital data to be input to the one or more arrays of computing-in-memory cells into analog data;
an analog-to-digital conversion module coupled to the one or more arrays of computing-in-memory cells and configured to convert analog data computed by the one or more arrays of computing-in-memory cells into digital data;
a phase-locked loop; and
an oscillator.

4. The computing-in-memory system according to claim 1, wherein
the peripheral analog circuit IP core includes one or more modules, and
wherein the second chip comprises one or more sub-chips, each of which includes one or more modules of the peripheral analog circuit IP core or a combination thereof.

5. The computing-in-memory system according to claim 3, wherein the digital circuit IP core includes one or more of:
a post-processing operation circuit configured to perform a post-processing operation on digital data converted by the analog-to-digital conversion module;
a random-access memory (RAM);
a central processing unit (CPU);
a graphics processing unit (GPU); and
a peripheral interface module.

6. The computing-in-memory system according to claim 1, wherein
the digital circuit IP core includes one or more modules, and
wherein the second chip comprises one or more sub-chips each of which includes one or more modules of the digital circuit IP core or a combination thereof.

7. The computing-in-memory system according to claim 1, wherein the one or more arrays of computing-in-memory cells are integrated, through a first process node, on the plurality of first chips, and the peripheral analog circuit IP core and the digital circuit IP core are integrated, through a second process node different from the first process node, on the second chip.

8. The computing-in-memory system according to claim 7, wherein a line width of the second process node is less than a line width of the first process node.

9. The computing-in-memory system according to claim 1, wherein the one or more arrays of computing-in-memory cells, and the peripheral analog circuit IP core and the digital circuit IP core are respectively integrated, through a same process node, on each first chip and the second chip.

10. A method comprising:
integrating one or more arrays of computing-in-memory cells of a computing-in-memory system on a plurality of first chips arranged to overlap each other, wherein the one or more arrays of computing-in-memory cells are configured to perform computations on received data;
integrating a peripheral analog circuit IP core and a digital circuit IP core of the computing-in-memory system on a second chip; and
packaging the plurality of first chips and the second chip, wherein the second chip is communicatively coupled to each first chip.

11. The method according to claim 10, wherein the second chip is communicatively coupled to each of the plurality of first chips via a through-silicon via (TSV).

12. The method according to claim 10, wherein
integrating the one or more arrays of computing-in-memory cells of the computing-in-memory system on the plurality of first chips comprises: integrating, through a first process node, the one or more arrays of computing-in-memory cells on the plurality of first chips, and
integrating the peripheral analog circuit IP core and the digital circuit IP core of the computing-in-memory system on the second chip comprises: integrating, through a second process node different from the first process node, the peripheral analog circuit IP core and the digital circuit IP core on the second chip.

13. The method according to claim 12, wherein a line width of the second process node is less than a line width of the first process node.

14. The method according to claim 10, wherein the one or more arrays of computing-in-memory cells, and the peripheral analog circuit IP core and the digital circuit IP core are integrated, through a same process node, on each of the plurality of first chips and on the second chip, respectively.

15. The method according to claim 10, wherein the peripheral analog circuit IP core includes one or more of:
a programming circuit module coupled to the one or more arrays of computing-in-memory cells and configured to perform data programming on the one or more arrays of computing-in-memory cells;
a digital-to-analog conversion module coupled to the one or more arrays of computing-in-memory cells and configured to convert digital data to be input to the one or more arrays of computing-in-memory cells into analog data;
an analog-to-digital conversion module coupled to the one or more arrays of computing-in-memory cells and configured to convert analog data computed by the one or more arrays of computing-in-memory cells into digital data;
a phase-locked loop; and
an oscillator.

16. The method according to claim 10, wherein
the peripheral analog circuit IP core includes one or more modules, and
the second chip includes one or more sub-chips that each include any of the one or more modules of the peripheral analog circuit IP core or a combination thereof.

17. The method according to claim 15, wherein the digital circuit IP core includes one or more of:
a post-processing operation circuit configured to perform a post-processing operation on the digital data converted by the analog-to-digital conversion module;
a random-access memory (RAM);
a central processing unit (CPU);
a graphics processing unit (GPU); and
a peripheral interface module.

18. The method according to claim 10, wherein
the digital circuit IP core includes one or more modules, and
the second chip includes one or more sub-chips that each include any of the one or more modules of the digital circuit IP core or a combination thereof.

19. An apparatus comprising a computing-in-memory system which comprises:
a plurality of first chips that each include one or more arrays of computing-in-memory cells of a computing-in-memory system, and that are arranged to overlap each other, wherein the one or more arrays of computing-in-memory cells are configured to perform computations on received data;
a second chip that includes a peripheral analog circuit IP core and a digital circuit IP core of the computing-in-memory system; and
an interface module configured to communicatively couple the second chip to each first chip.

20. The apparatus according to claim 19, wherein the interface module comprises a through-silicon via (TSV) structure.
